(19) United States
(12) Patent Application Publication
(10) Pub. No.: US 2004/0264231 A1
(43) Pub. Date: Dec. 30, 2004

(54) Portable electronic device capable of protecting specific block of flash memory chip

(75) Inventors: Show-Nan Chung, Sinjhaung City (TW); Chun-Chang Chen, Taipei City (TW); Chin-Peng Tsai, Sindian City (TW)

Correspondence Address: BACON & THOMAS, PLLC, 625 SLATERS LANE, FOURTH FLOOR, ALEXANDRIA, VA, 22314

(73) Assignee: Tatung Co., Ltd., Taipei City (TW)

(21) Appl. No.: 10/851,138

(22) Filed: May 24, 2004

(30) Foreign Application Priority Data
Dec. 9, 2002 (TW) 091219908

(51) Int. Cl. G11C 11/22

(52) U.S. Cl. 365/145

(57) ABSTRACT

A portable electronic device capable of protecting a specific block of flash memory chips thereof is disclosed. It comprises at least one flash memory chip, a processor, and a programmable logic device. The flash memory chip stores a bootstrap, an embedded OS, and applications. The processor executes the bootstrap, the embedded OS, and the applications. The programmable logic device decodes address lines, write signals, and read signals of the processor so that when the processor is about to write data into the predetermined block of the flash memory chip, the programmable logic device neither generates a RDY# signal nor sends the RDY# signal to the processor for representing a write failure, and a write signal into the flash memory chip is masked so that the block of the flash memory chip is protected.

### BACKGROUND OF THE INVENTION

1. Field of the Invention

The present invention relates to the technical field of flash memory chip access and, more particularly, to a portable electronic device capable of protecting a specific block of flash memory chip.

2. Description of Related Art

More and more electronic products (e.g., Palm computers, PDAs (Personal Digital Assistants), smart displays, etc.) are miniaturized due to the improvement of fabrication of integrated circuit (IC). Such portable electronic device has a processor for processing data and storing bootstrap, embedded OS (operating system), and applications in the flash memory chip. FIG. 1 shows circuitry of a conventional portable electronic device with a processor 10 and flash memory chips 12. Typically, a memory controller 11 for the flash memory chips 12 (or other type of memory chip) is integrated into the processor 10 for reducing the size of the portable electronic device. Adding buffers 13 and flash memory chips 12 and configuring the registers of the memory controller 11 will carry out an access to the external flash memory chips 12. As an end, the size of the portable electronic device can be reduced and a great use convenience can be obtained.

However, the conventional memory controller 11 for the flash memory chips 12 suffers from some disadvantages. For example, a user may accidentally write data into system blocks of the flash memory chips 12 of the portable electronic device or the embedded OS while running an application. This can corrupt the embedded OS of the portable electronic device or even crash the startup mechanism and self-modifying capability thereof. Therefore, it is desirable to provide an improved device to mitigate and/or obviate the aforementioned problems.

### SUMMARY OF THE INVENTION

An object of the present invention is to provide a portable electronic device capable of protecting a specific block of flash memory chip to prevent the crash of the embedded OS of the portable device.

To achieve the object, there is provided a portable electronic device capable of protecting a specific block of flash memory chip thereof. It comprises at least one flash memory chip, a processor, and a programmable logic device. The flash memory chip stores a bootstrap, an embedded OS, and applications. The processor executes the bootstrap, the embedded OS, and the applications. The programmable logic device decodes address lines, write signals, and read signals of the processor so that when the processor is about to write data into the predetermined block of the flash memory chip, the programmable logic device neither generates a RDY# signal nor sends the RDY# signal to the processor for representing a write failure, and a write signal into the flash memory chip is masked so that of the block the flash memory chip is protected.

Other objects, advantages, and novel features of the present invention will become more apparent from the detailed description when taken in conjunction with the accompanying drawings.

### BRIEF DESCRIPTION OF THE DRAWINGS

FIG. 1 is a circuit diagram of a processor, flash memory chips and other associated components of a conventional portable electronic device; and

FIG. 2 is a circuit diagram of a portable electronic device with protecting a specific block of flash memory chip according to the present invention.

### DETAILED DESCRIPTION OF THE PREFERRED EMBODIMENT

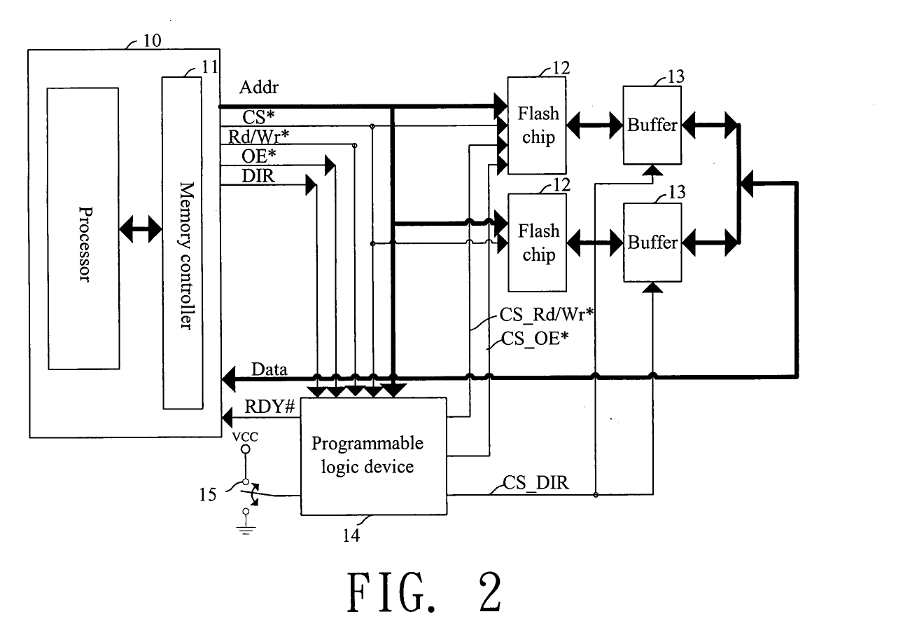

FIG. 2 is a block diagram of a portable electronic device capable of protecting a specific block of flash memory chip in accordance with the present invention. The portable electronic device comprises at least one flash memory chip 12, at least one buffer 13, a processor 10, a programmable logic device 14 and a switch 15. The flash memory chip 12 is implemented as a NOR type of flash memory for storing bootstrap, embedded OS, and applications of the portable device. The processor 10 is adapted to run the bootstrap, the embedded OS, and the applications.

The processor 10 always fetches data from a predetermined address (e.g., addressed at 00000000H) after powering on. The flash memory chip 12 will be mapped to the predetermined address (e.g., addressed at 00000000H) such that the processor 10 can access the data thereof. Further, the bootstrap is stored in the flash memory chip 12 at predetermined address so that the processor 10 can run the bootstrap and load the embedded OS after powering on. The portable electronic device may operate abnormally or even cannot startup if the bootstrap or the embedded OS is corrupted.

The present invention uses hardware to protect the block of the flash memory chip 12 for storing the bootstrap and the embedded OS and thus for preventing the block from being corrupted accidentally while in use. The size of the protected block is based on the size of the bootstrap and the embedded OS. For example, the size of the block is 1M byte if the total size of the bootstrap and the embedded OS is 600K byte. That is, a block addressed from 00000000H to 00100000H is protected by hardware.

First, the processor 10 configures the register of the memory controller 11 for detecting a ready (RDY#) signal when the processor 10 accesses the flash memory chips 12. When the processor 10 detects RDY# signal, this means that the access is successful. Otherwise, the access is failure.

The programmable logic device 14 is adapted to protect a predetermined block of the flash memory chip 12 that is addressed from 00000000H to 00100000H. The programmable logic device 14 decodes address lines, write signals, and read signals of the processor 10. When the processor 10 try to write data into the predetermined block addressed from 00000000H to 00100000H of the flash memory chip 12, the programmable logic device 14 does not generate a RDY# signal and does not send the RDY# signal to the processor 10 for representing a write failure. Further, a write signal CS_Rd/Wr* into the flash memory chip 12 is masked. As a result, the writing of the flash memory chip 12 is protected.

The programmable logic device 14 generates a RDY# signal based on timing of the flash memory chip 12 and sends the RDY# signal to the processor 10 as a representation of success when the processor 10 reads data from the predetermined block addressed from 00000000H to 00100000H of the flash memory chip 12 or writes data into the block other than the predetermined block addressed from 00000000H to 00100000H. At the same time, control signals are generated and are sent to the flash memory chip 12 for accessing.

The present invention further comprises a switch 15 having one connection end coupled to a pin of the programmable logic device 14, and a first switching end coupled to a high voltage level and a second switching end coupled to a low voltage level. When the switch 15 is switched to couple the connection end to the first switching end, the programmable logic device 14 can perform a write protection to the predetermined block addressed from 00000000H to 00100000H of the flash memory chips 12. On the contrary, when the switch 15 is switched to couple the connection end to the second switching end, the programmable logic device 14 can perform write and read operations with respect to the predetermined block addressed from 00000000H to 00100000H of the flash memory chips 12. As an end, the bootstrap or the embedded OS can be updated.

In viewing of foregoing, it is known that the present invention uses the programmable logic device 14 to protect the predetermined block of the flash memory chips 12 while writing. This can prevent the block from being corrupted accidentally while in use. As an end, the problem of the portable electronic device being malfunctioned or being unable to start can be overcome.

Although the present invention has been explained in relation to its preferred embodiment, it is to be understood that many other possible modifications and variations can be made without departing from the spirit and scope of the present invention as hereinafter claimed.

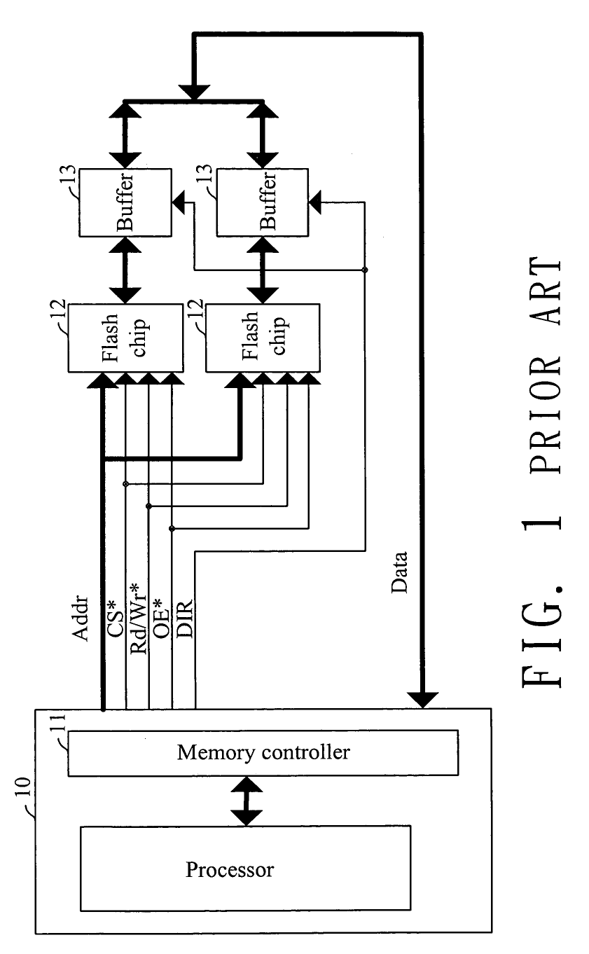

FIG. 1

processor 10

memory controller 11

flash memory chip 12

flash memory chip 12

buffer 13

buffer 13

FIG. 2

processor 10

memory controller 11

flash memory chip 12

flash memory chip 12

buffer 13

buffer 13

programmable logic device 14

What is claimed is:

1. A portable electronic device capable of protecting a specific block of flash memory chips thereof, comprising:
at least one flash memory chip for storing a bootstrap, an embedded OS, and applications;
a processor for running the bootstrap, the embedded OS, and the applications; and
a programmable logic device for protecting a predetermined block of each flash memory chip,
wherein the programmable logic device decodes address lines, write signals, and read signals of the processor so that when the processor is about to write data into the predetermined block of the flash memory chip, the programmable logic device neither generates a ready signal nor sends the ready signal to the processor for representing a write failure, and a write signal into the flash memory chip is masked so that of the block the flash memory chip is protected.

2. The portable electronic device as claimed in claim 1, wherein the flash memory chip is a NOR type of flash memory.

3. The portable electronic device as claimed in claim 1, further comprising a switch having one connection end coupled to a pin of the programmable logic device, and a first switching end and a second switching end so that when the connection end of the switch is switched to the first switching end, the programmable logic device is operative to perform a write protection to the predetermined block of the flash memory chip or when the connection end of the switch is switched to the second switching end, the programmable logic device is operative to perform write and read operations with respect to the predetermined block of the flash memory chip.

4. The portable electronic device as claimed in claim 3, wherein the first switching end of the switch is coupled to a high voltage level and the second switching end of the switch is coupled to a low voltage level.
